(19) United States
(12) Patent Application Publication
(10) Pub. No.: US 2011/0298341 A1
(43) Pub. Date: Dec. 8, 2011

(54) ENCLOSURE OF ELECTRONIC DEVICE

(75) Inventors: Chien-Hung Liu, Tu-Cheng (TW); Yu-Chang Pai, Tu-Cheng (TW); Po-Chuan Hsieh, Tu-Cheng (TW); Shou-Kuo Hsu, Tu-Cheng (TW)

(73) Assignee: HON HAI PRECISION INDUSTRY CO., LTD., Tu-Cheng (TW)

(21) Appl. No.: 12/859,283

(22) Filed: Aug. 19, 2010

(30) Foreign Application Priority Data
Jun. 7, 2010 (TW) 99118296

(51) Int. Cl. H05K 5/02

(52) U.S. Cl. 312/223.1

(57) ABSTRACT

An enclosure of an electronic device includes a plate. The plate defines a number of through holes with a number of shields. Each shield includes a tab apart from the plate. At least two spaced connection pieces connect the tab to a corresponding through hole in such a way that the tab is substantially aligned with and spaced from the corresponding through hole.

### CROSS-REFERENCE TO RELATED APPLICATIONS

Relevant subject matter is disclosed in the co-pending U.S. patent applications (Attorney Docket Nos. US32221, US32384, US32670, US32874, US32875, US33505) having the same title and are assigned to the same assignee as named herein.

### BACKGROUND

1. Technical Field

The present disclosure relates to an enclosure of an electronic device.

2. Description of Related Art

For the enclosure of a typical electronic device, electromagnetic interference (EMI) is a common problem during operation. Commonly, through holes are defined in the enclosure for aiding in heat dissipation, and though sizes and placement of the holes are chosen and arranged to help avoid EMI, problems from EMI still occur.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of a plate in an exemplary embodiment of enclosure of an electronic device.

FIG. 2 is another isometric view of the plate of FIG. 1.

FIG. 3 is a side view of the plate of FIG. 1.

FIG. 4 is a graph showing EMI shielding effectiveness of a conventional enclosure and an enclosure using the plate of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

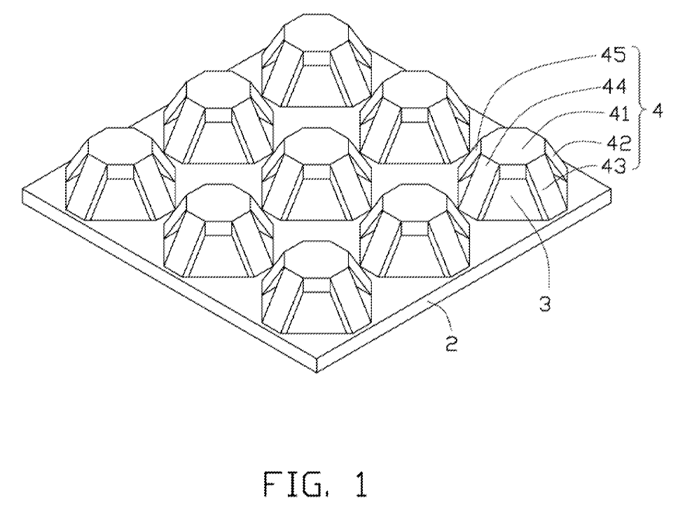

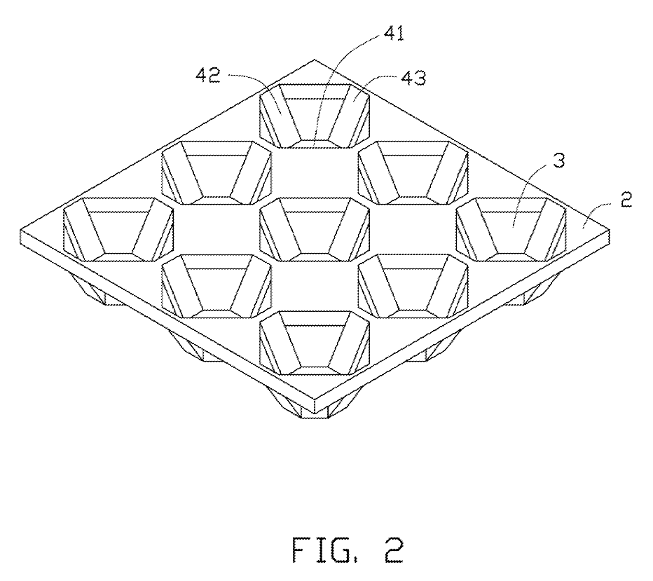

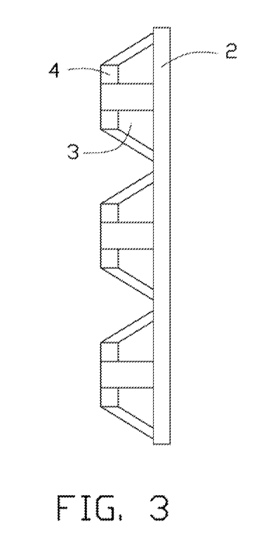

Referring to FIGS. 1 to 3, an exemplary embodiment of an enclosure of an electronic device includes a plate 2. The plate 2 can be arranged on a front side or a back side of the enclosure.

The plate 2 defines a plurality of through holes 3, with a plurality of shields 4 being set inside of the enclosure. Each through hole 3 is octagon-shaped. Each shield 4 includes a tab 41 parallel to the plate 2, and four connection pieces 42, 43, 44, and 45 slantingly connected between the plate 2 and the tab 41. The tab 41 is octagon-shaped and the size of the tab 41 is smaller than the through hole 3. The connection pieces 42, 43, 44, and 45 are connected at every other side of the sides bounding the through hole 3 and corresponding every side of the sides bounding the tab 41. Each tab 41 is substantially aligned with and spaced from the corresponding through hole 3. As a result, heat inside the enclosure can be vented to the outside through the through holes 3 and interspaces bounded by the tabs 41, the plates 2, and the corresponding connection pieces 42, 43, 44, and 45.

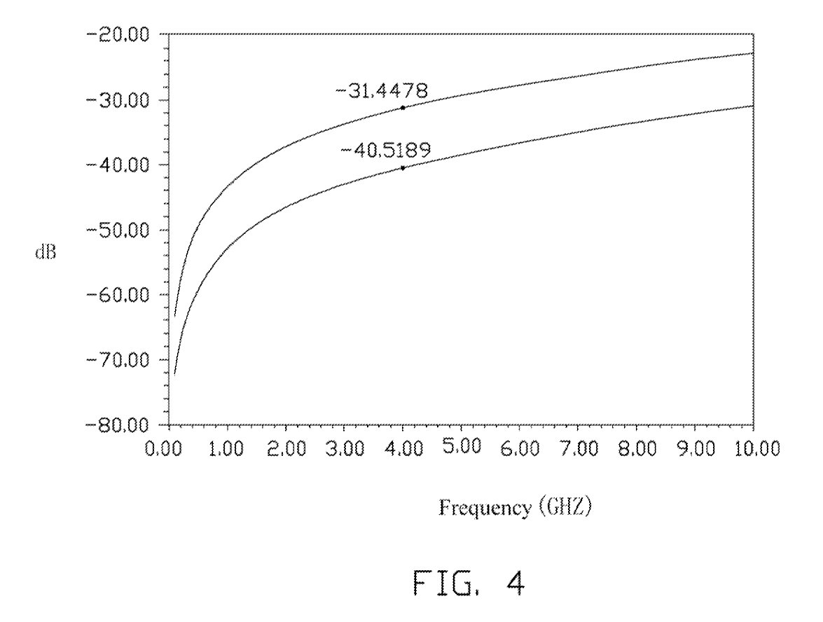

Referring to FIG. 4, a curve A1 represents EMI shielding effectiveness of a conventional enclosure. A curve A2 represents EMI shielding effectiveness of the enclosure with the plate 2 of FIG. 1. FIG. 4 clearly indicates that the EMI shielding effectiveness of the enclosure with the plate 2 is better than the EMI shielding effectiveness of the conventional enclosure.

In other embodiments, each shield 4 may include two spaced connection pieces forming two sides of the tab 41 and bounding the through hole 3. At this condition, heat inside the enclosure can be vented to the outside through the through holes 3 and interspaces bounded by the tabs 41, the plates 2, and the two connection pieces. In other words, each shield 4 extends outwards from a circumference of a corresponding through hole. A sidewall of each shield defines at least one opening.

Furthermore, in other embodiments, the size and shape of the tab 41 of the shield 4 can be changed according to need. When the shields 4 are configured with a different size and a different shape, the EMI shielding effectiveness of the enclosure may be different. In addition, shape of the through holes 3 may be round or other shapes. Furthermore, the length of the connection pieces can be changed according to need. When the connection pieces have different lengths, the EMI shielding effectiveness of the enclosure may be different.

The foregoing description of the embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. An enclosure of an electronic device, the enclosure comprising a plate, wherein the plate defines a plurality of through holes with a plurality of shields, each shield comprises a tab apart from the plate, and at least two spaced connection pieces connecting the tab to a corresponding through hole in such a way that the tab is substantially aligned with and spaced from the corresponding through hole.

2. The enclosure of claim 1, wherein each through hole is octagon-shaped.

3. The enclosure of claim 2, wherein the tab is octagon-shaped, parallel to the plate, and smaller than the through hole.

4. The enclosure of claim 3, wherein the at least two spaced connection pieces comprise four connection pieces slantingly connected at every other side of the sides bounding the corresponding through hole and corresponding every side of the sides of the tab.

5. An enclosure of an electronic device, the enclosure comprising a plate, wherein the plate defines a plurality of through holes, a shield extends outwards from a side bounding each through hole, a sidewall of each shield defines at least one opening.
